(19) United States
(12) Patent Application Publication
(10) Pub. No.: US 2012/0025196 A1
(43) Pub. Date: Feb. 2, 2012

(54) ORGANIC THIN FILM TRANSISTOR AND SEMICONDUCTOR INTEGRATED CIRCUIT

(75) Inventors: Yasuo Wada, Bunkyo-ku (JP); Toru Toyabe, Fujimi-shi (JP); Ken Tsutsui, Tokyo (JP)

(73) Assignee: TOYO UNIVERSITY, Tokyo (JP)

(21) Appl. No.: 13/263,122

(22) PCT Filed: Jan. 18, 2010
(86) PCT No.: PCT/JP2010/050491

§ 371 Date: Oct. 6, 2011

(30) Foreign Application Priority Data
Apr. 8, 2009 (JP) 2009-094202

(51) Int. Cl. H01L 51/10

(52) U.S. Cl. 257/66; 257/40; 257/E51.006

(57) ABSTRACT

An organic thin film transistor includes an organic semiconductor layer, a source electrode and a drain electrode which are separated from each other and are individually in contact with the organic semiconductor layer, a gate insulating film which is in contact with the organic semiconductor layer between the source and drain electrodes, and a gate electrode which is opposed to the organic semiconductor layer and is in contact with the gate insulating film. In the organic thin film transistor, a high-concentration region of the organic semiconductor layer which is located near the source electrode has an impurity concentration set higher than an impurity concentration of a low-concentration region of the organic semiconductor layer, the low-concentration region being located near the gate electrode in the thickness direction of the organic semiconductor layer between the source and drain electrodes.

### TECHNICAL FIELD

The invention relates to an organic thin film transistor and a semiconductor integration circuit including an organic semiconductor layer.

### BACKGROUND ART

Organic thin film transistors (organic TFTs) using organic semiconductor layers made of organic materials having semiconductive characteristics as channel regions are attracting attention as main devices for printable devices, flexible devices, and the like. In metal oxide semiconductor field effect transistors (MOSFETS) and poly-crystalline silicon thin film transistors (poly-Si TFTs), drain current flows when carrier inversion layers are formed in the semiconductors. In contrast, in organic thin film transistors, drain current flows when carrier accumulation layers are formed.

In an organic thin film transistor, when gate voltage is applied to the gate electrode, carriers are accumulated in the organic semiconductor layer. By applying drain voltage across the source and drain electrodes, drain current flows through a part of the organic semiconductor layer serving as a channel region. The operation of such an organic thin film transistor can be simulated by device simulation based on Poisson's equation and a continuity equation as described in NPL 1, for example.

If organic semiconductors are p-type, carriers are holes. Generally, holes in organic semiconductors have low mobility, but some materials found by search, improvement, and the like have high mobility. For example, use of an acene compound such as pentacene allows realization of an organic thin film transistor having a characteristic of mobility of about 1 to 10 cm²/V·s (for example, see NPL 2).

### CITATION LIST

### Non Patent Literature

[NPL 1] Y. Nakajima, et al. “Confirmation of electric properties of traps at silicon-on-insulator (SOI)/buried oxide (BOX) interface by three-dimensional device simulation”, Physica E, 24, Jan. 2004, p. 92-95.
[NPL 2] Wada, two others, “Prospects for molecular nanoelectronics”, Applied Physics, 2001, vol. 70, No. 12, p. 1395-1406

### SUMMARY OF INVENTION

### Technical Problem

However, the organic thin film transistors having the aforementioned level of characteristics can be used as pixel transistors but are inadequate to be used in peripheral circuits of flexible displays and the like, for example. The characteristics of organic thin film transistors need to be further improved. The reason why conventional organic thin film transistors cannot have adequate characteristics is that lack of carriers in the organic semiconductor layer causes an electric field drop. The organic thin film transistors therefore have small apparent current amplification factors.

In the light of the aforementioned problems, an object of the invention is to provide an organic thin film transistor and a semiconductor integration circuit including an organic semiconductor layer with the lack of carriers prevented.

### Solution of Problem

According to an aspect of the invention, an organic thin film transistor is provided, which includes: an organic semiconductor layer; a source electrode and a drain electrode which are separated from each other and are individually in contact with the organic semiconductor layer; a gate insulating film which is in contact with the organic semiconductor layer between the source and drain electrodes; and a gate electrode which is opposed to the organic semiconductor layer and is in contact with the gate insulating film. In the organic thin film transistor, a high-concentration region of the organic semiconductor layer which is located near the source electrode has an impurity concentration higher than an impurity concentration of a low-concentration region of the organic semiconductor layer, the low-concentration region being located near the gate electrode in the thickness direction of the organic semiconductor layer between the source and drain electrodes.

According to another aspect of the invention, an organic thin film transistor is provided, which includes: a substrate; and first and second transistors, each including: an organic semiconductor layer; a source electrode and a drain electrode which are separated from each other and are individually in contact with the organic semiconductor layer; a gate insulating film which is in contact with the organic semiconductor layer between the source and drain electrodes; and a gate electrode which is opposed to the organic semiconductor layer and is in contact with the gate insulating film. In the first transistor, a high-concentration region of a first conductivity type in the organic semiconductor layer which is located near the source electrode has an impurity concentration higher than an impurity concentration of a low-concentration region in the organic semiconductor layer, the low-concentration region being located near the gate electrode in the thickness direction of the organic semiconductor layer between the source and drain electrodes. In the second transistor, a high-concentration region of a second conductivity type in the organic semiconductor layer which is located near the source electrode has an impurity concentration higher than an impurity concentration of a low-concentration region in the organic semiconductor layer, the low-concentration region being located near the gate electrode in the thickness direction of the organic semiconductor layer between the source and drain electrodes.

According to still another aspect, a semiconductor integrated circuit including the above organic thin film transistor is provided.

### Advantageous Effects of Invention

According to the invention, it is possible to provide an organic thin film transistor and a semiconductor integrated circuit with lack of carriers in an organic semiconductor layer prevented.

### BRIEF DESCRIPTION OF DRAWINGS

FIG. 1 is a schematic cross-sectional view showing a structure of an organic thin film transistor according to a first embodiment of the invention.

FIG. 2 is a schematic cross-sectional view showing a structure of a comparative example.

FIG. 3(a) is a graph showing device simulation results of the comparative example, and FIG. 3(b) is a graph showing device simulation results of the organic thin film transistor according to the first embodiment of the invention.

FIG. 4 is a graph showing device simulation results of the organic thin film transistor according to the first embodiment of the invention for varying thickness of a high-concentration region.

FIG. 5 is a graph showing device simulation results of the organic thin film transistor according to the first embodiment of the invention for varying impurity concentration of the high-concentration region.

FIG. 6 is a graph showing device simulation results of the organic thin film transistor according to the first embodiment of the invention for varying thickness of the organic semiconductor layer.

FIG. 7 is a graph showing device simulation results of the organic thin film transistor according to the first embodiment of the invention for varying thickness of a gate insulation layer.

FIG. 8 is a cross-sectional process view (No. 1) for explaining a method of manufacturing the organic thin film transistor according to the first embodiment of the invention.

FIG. 9 is a cross-sectional process view (No. 2) for explaining the method of manufacturing the organic thin film transistor according to the first embodiment of the invention.

FIG. 10 is a cross-sectional process view (No. 3) for explaining a method of manufacturing the organic thin film transistor according to the first embodiment of the invention.

FIG. 11 is a cross-sectional process view (No. 4) for explaining a method of manufacturing the organic thin film transistor according to the first embodiment of the invention.

FIG. 12 is a cross-sectional process view (No. 5) for explaining a method of manufacturing the organic thin film transistor according to the first embodiment of the invention.

FIG. 13 is a cross-sectional process view (No. 1) for explaining another method of manufacturing the organic thin film transistor according to the first embodiment of the invention.

FIG. 14 is a cross-sectional process view (No. 2) for explaining another method of manufacturing the organic thin film transistor according to the first embodiment of the invention.

FIG. 15 is a cross-sectional process view (No. 3) for explaining another method of manufacturing the organic thin film transistor according to the first embodiment of the invention.

FIG. 16 is a schematic cross-sectional view showing a structure of an organic thin film transistor according to a modification according to the first embodiment of the invention.

FIG. 17(a) is a graph showing device simulation results of the organic thin film transistor shown in FIG. 1, and FIG. 17(b) is a graph showing device simulation results of the organic thin film transistor shown in FIG. 16.

FIG. 18 is a schematic cross-sectional view showing a structure of an organic thin film transistor according to still another modification according to the first embodiment of the invention.

FIG. 19 is a schematic cross-sectional view showing a structure of an organic thin film transistor according to still another modification according to the first embodiment of the invention.

FIG. 20 is a schematic cross-sectional view showing a structure of an organic thin film transistor according to a second embodiment of the invention.

FIG. 21 is a graph showing results of device simulation of the organic thin film transistor according to the second embodiment of the invention for varying carrier concentration of a low-concentration region.

FIG. 22 is a graph showing other results of device simulation of the organic thin film transistor according to the second embodiment of the invention for varying carrier concentration of a low-concentration region.

FIG. 23 is a cross-sectional process view (No. 1) for explaining a method of manufacturing the organic thin film transistor according to the second embodiment of the invention.

FIG. 24 is a cross-sectional process view (No. 2) for explaining the method of manufacturing the organic thin film transistor according to the second embodiment of the invention.

FIG. 25 is a cross-sectional process view (No. 3) for explaining the method of manufacturing the organic thin film transistor according to the second embodiment of the invention.

FIG. 26 is a schematic cross-sectional view showing a structure of an organic thin film transistor according to a modification according to the second embodiment of the invention.

FIG. 27 is a schematic cross-sectional view showing a structure of an organic thin film transistor according to another modification according to the second embodiment of the invention.

FIG. 28 is a schematic view showing a configuration example of a semiconductor integrated circuit including the organic thin film transistor according to the second embodiment of the invention.

### DESCRIPTION OF EMBODIMENTS

Next, first and second embodiments of the invention are described with reference to the drawings. In the following description of the drawings, same or similar portions are given same or similar reference numerals. It should be noted that the drawings are schematic and that the relation between thickness and planer dimensions, the proportion of thicknesses of layers, and the like are different from the real ones. Accordingly, specific thicknesses and dimensions should be determined with reference to the following description. It is certain that some portions have different dimensional relations and proportions through the drawings.

The first and second embodiments shown below show devices and methods to embody the technical idea of the invention by example. The embodiments of the invention do not specify the materials, shapes, structures, arrangements, and the like of the constituent components as shown below. The embodiments of the invention can be variously changed within the scope of claims.

### First Embodiment

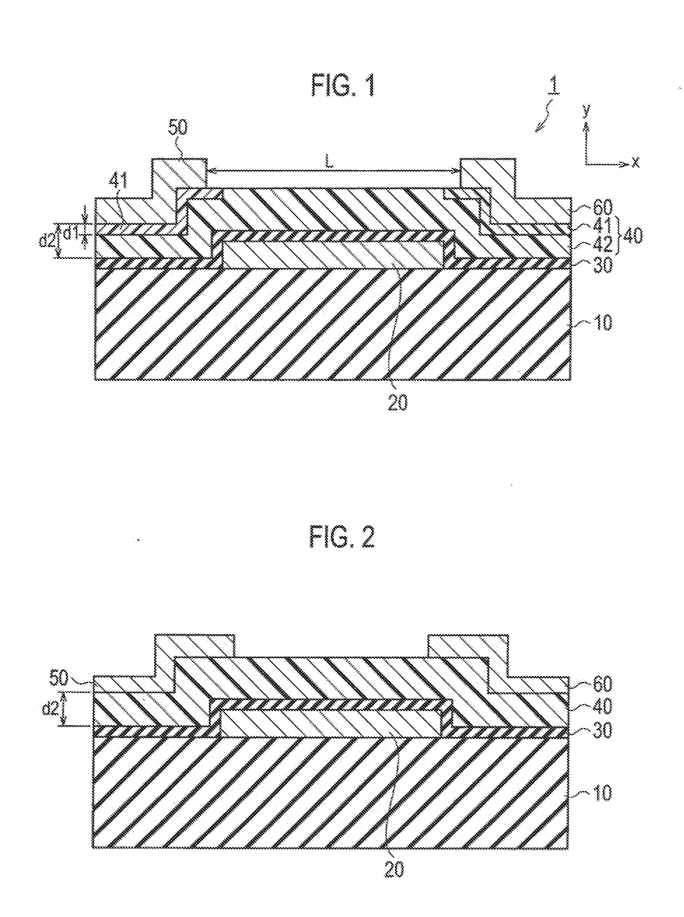

As shown in FIG. 1, an organic thin film transistor 1 according to the first embodiment of the invention includes: an organic semiconductor layer 90; source and drain electrodes 50 and 60 which are separated from each other and are in contact with the organic semiconductor layer 40; a gate insulating film 30 which is in contact with the organic semiconductor layer 90 between the source and drain electrodes 50 and 60; and a gate electrode 20 which is opposed to the organic semiconductor layer 40 and is in contact with the gate insulating film 30. The impurity concentration of a high-concentration region 41 of the organic semiconductor layer 40 which is located near the source electrode 50 is set higher than that of a low-concentration region 42 of the organic semiconductor layer 90. The low-concentration region 42 is located near the gate electrode 20 in the thickness direction of the organic semiconductor layer 90 between the source and drain electrodes 50 and 60. In other words, the impurity concentration of the high-concentration region 91, which is located near the source and drain electrodes 50 and 60 in the thickness direction of the organic semiconductor layer 40, is higher than the impurity concentration of the channel region of the organic thin film transistor 1. In FIG. 1, the thickness direction of the organic semiconductor layer 40 is indicated as a direction y, and the direction of channel length L is indicated as a direction x.

In the first embodiment shown in FIG. 1, the organic semiconductor layer 40 is located above the gate electrode 20, and the source and drain electrodes 50 and 60 are located on the organic semiconductor layer 40. The organic thin film transistor 1 shown in FIG. 1 therefore includes: the gate electrode 20 located on a substrate 1; the gate insulating film 30 located on the gate electrode 20; the organic semiconductor layer 40 located on the gate insulating film 30; and the source and drain electrodes 50 and 60 which are located on the organic semiconductor layer 40 to be separated from each other. The impurity concentrations of the high-concentration regions 41 of the organic semiconductor layer 40 individually located under the source and drain electrodes 50 and 60 are set higher than the impurity concentration of the low-concentration region 42 of the organic semiconductor layer 40 which is located above the gate electrode 20 between the source and drain electrodes 50 and 60.

In the organic thin film transistor 1 shown in FIG. 1, when a predetermined gate voltage Vg is applied to the gate electrode 20, carriers are accumulated in the gate insulating film 30 side of the organic semiconductor layer 40. If drain voltage is applied across the source and drain electrodes 50 and 60 with the carriers being accumulated in the organic semiconductor layer 40, drain current flows between the source and drain electrodes 50 and 60. In other words, the organic thin film transistor 1 operates using the organic semiconductor layer 40 above the gate electrode 20 as the channel region. Channel length L is a distance between the source and drain electrodes 50 and 60.

The substrate 10 can be an insulator substrate. For example, a plurality of the organic thin film transistors 1 are formed on a silica substrate, and the silica substrate is diced into chips, thus obtaining the individual organic thin film transistors 1.

The gate electrode 20 can be made of a conductive film such as a metallic film of aluminum (Al), molybdenum (Mo), or tungsten (W) or a polysilicon film. The gate insulating film 30 can be a silicon oxide film, a silicon nitride film, a high-k film having a high permittivity, or the like.

The organic semiconductor layer 40 is made of an organic material having semiconductor characteristics. The p-type material of the organic semiconductor layer 40 can be pentacene or the like, and the p-type impurities applied to the high-concentration regions 41 can be iodine or ionic molecules such as tetrathiofulvalene (TTF) and tetracyanoquinodimethane (TCNQ), for example. In the following description, the organic semiconductor layer 40 is a p-type semiconductor, or the carriers moving in the channel region are holes. In the example shown in FIG. 1, a part of upper portions of the organic semiconductor region 41 in contact with the source and drain electrodes 50 or 60 is the high-concentration region 41, and the other region is the low-concentration region 42 having a lower impurity concentration than the impurity concentration of the high-concentration region 41.

The source and drain electrodes 50 and 60 can be made of calcium (Ca), Al, gold (Au), or the like, for example.

FIG. 2 shows an organic thin film transistor of a comparative example for a comparison of characteristics with the organic thin film transistor 1 according to the first embodiment of the invention. The comparative example shown in FIG. 2 differs from the organic thin film transistor 1 shown in FIG. 1 in that the organic semiconductor layer 40 is composed of only the low-concentration region and does not include the high-concentration region.

In the organic thin film transistor 1 and comparative example used in device simulation whose results are shown below, the channel length L is 5 μm; channel width is 10 μm; thickness d2 of the organic semiconductor layer 40 is 50 nm; impurity concentration N2 of the low-concentration region 42 is 1×10¹⁵ cm⁻³; and thickness dg of the gate insulating film 30 is 300 nm. Thickness d1 of the high-concentration regions 41 of the organic thin film transistor 1 is 5 nm; and impurity concentration N1 thereof is 1×10²⁰ cm⁻³.

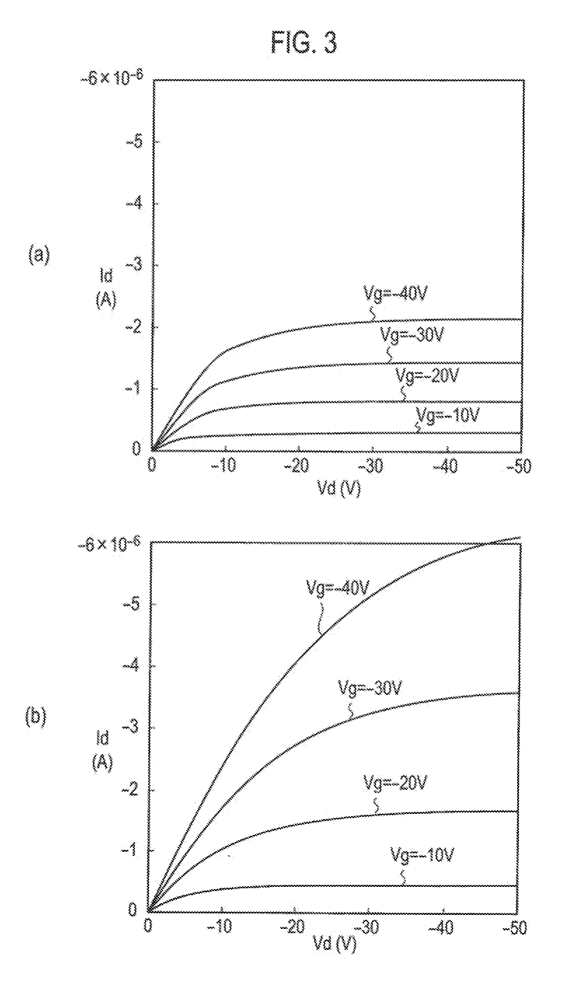

FIGS. 3(a) and 3(b) show calculation results of device simulation for the electric characteristics of the comparative example shown in FIG. 2 and the organic thin film transistor 1 shown in FIG. 1, respectively. The electric characteristics shown in FIGS. 3(a) and 3(b) are current-voltage characteristics obtained by calculating drain current Id with drain voltage Vd varying between 0 to −50 V when the gate voltage Vg is set to −10, −20, −30, and −40 V.

The comparison between FIGS. 3(a) and 3(b) reveals that the current amplification factor of the organic thin film transistor 1 according to the first embodiment of the invention is about three times as high as that of the comparative example shown in FIG. 2.

This is because holes as carriers are supplied from the high-concentration regions 41 to the channel region above the gate electrode 20. The supply of holes prevents lack of carriers in the channel region, and an electric field drop therefore does not occur. Accordingly, the current amplification factor of the organic thin film transistor 1 is higher than that of the comparative example not including the high-concentration regions 41. Even if only one of the high-concentration regions 41 is formed near the source electrode 50, the lack of carriers in the channel region is prevented, and the current amplification factor of the organic thin film transistor 1 is improved.

The followings show the result of examination on the characteristics by device simulation for the organic thin film transistor 1 shown in FIG. 1 with the structures being varied.

### Examination Example 1

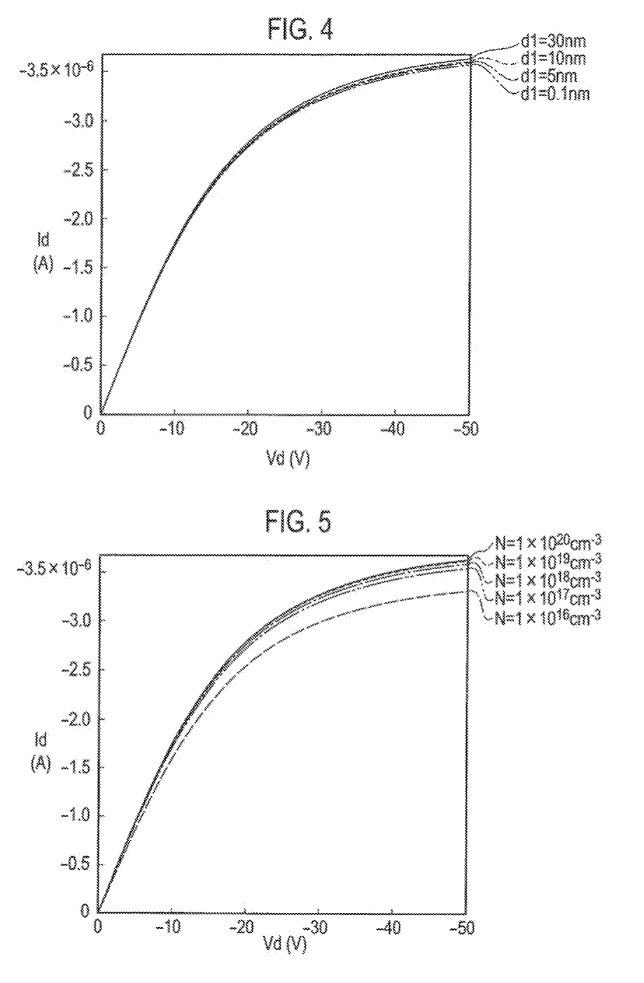

FIG. 4 shows current-voltage characteristics of the drain current Id and drain voltage Vd which are obtained by device simulation with the thickness d1 of the high-concentration region 41 of the organic thin film transistor 1 varying between 0.1 and 30 nm. Herein, the thickness d2 of the organic semiconductor layer 40 is 30 nm; the impurity concentration N2 of the low-concentration region 42 is 1×10¹⁵ cm⁻¹; and the impurity concentration N1 of the high-concentration regions 41 is 1×10²⁰ cm⁻³. The thickness dg of the gate insulating film 30 is 300 nm; the channel length L is 5 μm; the gate voltage Vg is −30 V; and the drain voltage Vd is 0 to −50V.

As shown in FIG. 4, the current-voltage characteristics are substantially the same for the thickness d1 of the high-concentration region 41 varying from 0.1 nm to 30 nm. Herein, when the thickness d1 is 30 nm, the entire regions of the organic semiconductor layer 40 under the source and drain electrodes 50 and 60 in the thickness direction thereof are the high-concentration regions 41. Accordingly, it is confirmed that the high-concentration regions 41 are effective on improving the characteristic of the organic thin film transistor 1 when the thickness d1 of the high-concentration regions 41 is at least not less than 0.1 nm.

### Examination Example 2

FIG. 5 shows current-voltage characteristics of the drain current Id and drain voltage Vd which are obtained by device simulation with the impurity concentration N1 of the high-concentration region 41 of the organic thin film transistor 1 varying between 1×10¹⁶ and 1×10²⁰ cm⁻³. Herein, the thickness d2 of the organic semiconductor layer 40 is 30 nm; the thickness d1 of the high-concentration region 41 is 5 nm; and the impurity concentration N2 of the low-concentration region 42 is 1×10¹⁵ cm⁻³. The thickness dg of the gate insulating film 30 is 300 nm; the channel length L is 5 μm; the gate voltage Vg is −30 V; and the drain voltage Vd is 0 to −50V.

As shown in FIG. 5, when the impurity concentration N1 of the high-concentration region 41 is not less than 1×10¹⁷ cm⁻³, the current-voltage characteristics thereof are substantially the same regardless of the impurity concentration N1. Accordingly, in order to obtain the effect on improving the characteristics of the organic thin film transistor 1, it is effective that the impurity concentration N1 of the high-concentration regions 41 is set to 1×10¹⁷ cm⁻³ or higher.

As shown in FIG. 5, the effect on improving the characteristics can be also obtained even if the impurity concentration N1 of the high-concentration region 91 is not less than 1×10¹⁶ cm⁻³. This is because the impurity concentration N2 of the low-concentration region 42 is set to 1×10¹⁵ cm⁻³. Therefore, when the impurity concentration N1 of the high-concentration regions 41 is higher than the impurity concentration N2 of the low-concentration region 42, the effect on improving the organic thin film transistor 1 can be obtained not only when the impurity concentration N2 is 1×10¹⁶ cm⁻³ or higher regardless of the values of the impurity concentrations N1 and N2.

### Examination Example 3

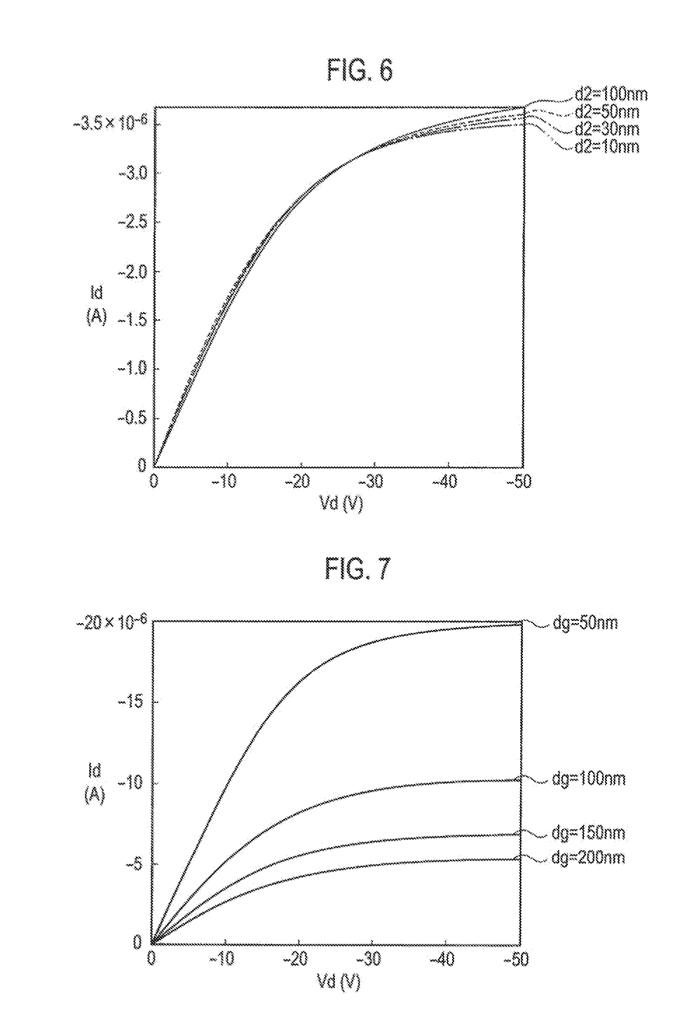

FIG. 6 shows current-voltage characteristics of the drain current Id and drain voltage Vd which are obtained by device simulation with the thickness d2 of the organic semiconductor layer 40 of the organic thin film transistor 1 varying between 10 and 100 nm. Herein, the impurity concentration N2 of the low-concentration region 42 is 1×10¹⁵ cm⁻³; the thickness d1 of the high-concentration region 41 is 5 nm; and the impurity concentration N1 of the high-concentration regions 41 is 1×10²° cm⁻³. The thickness dg of the gate insulating film 30 is 300 nm; the channel length L is 5 μm; the gate voltage Vg is −30 V; and the drain voltage Vd is 0 to −50V.

As shown in FIG. 6, the current-voltage characteristics are substantially the same regardless of the thickness d2 of the organic semiconductor layer 40. The thickness d2 of the organic semiconductor layer 40 very little affects the current-voltage characteristic of the organic thin film transistor 1. Accordingly, the thickness d2 of the organic semiconductor layer 40 can be arbitrarily set to obtain the effect on improving the characteristic of the organic thin film transistor 1.

### Examination Example 4

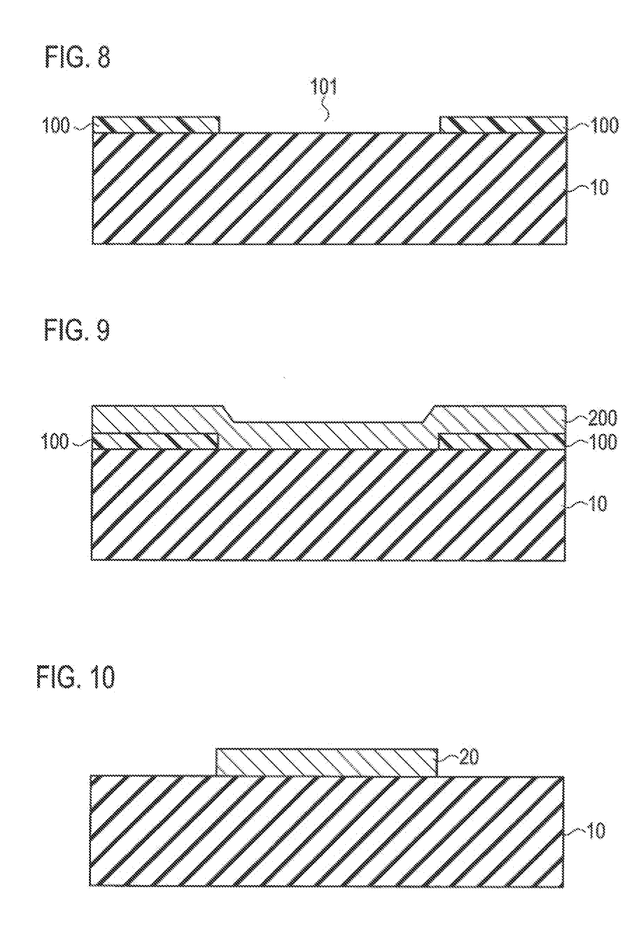

FIG. 7 shows the obtained current-voltage characteristics of the drain current Id and drain voltage Vd which are obtained by device simulation with the thickness dg of the gate insulating film 30 of the organic thin film transistor 1 varying between 50 and 200 nm. Herein, the thickness d2 of the organic semiconductor layer 40 is 30 nm; the impurity concentration N2 of the low-concentration region 42 is 1×10¹⁵ cm⁻³; the thickness d1 of the high-concentration regions 41 is 5 nm; and the impurity concentration N1 of the high-concentration regions 41 is 1×10²⁰ cm⁻³. The channel length L is 5 μm; the gate voltage Vg is −30 V; and the drain voltage Vd is 0 to −50V.

As shown in FIG. 7, the magnitude of the drain current Id is inversely proportional to the thickness dg of the gate insulating film 30 for a range of the thickness dg of the gate insulating film 30 from 50 to 300 nm. Such a current-voltage characteristic is similar to that of semiconductor devices including silicon semiconductors, such as MOSFETs. Accordingly, it is apparent that the effect on improving the characteristic of the organic thin film transistor 1 can be also obtained if the gate insulating film 30 is made very thin or if the gate insulating film 30 is composed of insulating film with high permittivity other than silicon oxide film or silicon nitride film. Generally, the thinner the thickness dg of the gate insulating film 30, the higher the effect on improving the characteristic of the organic thin film transistor 1.

As described above, according to the organic thin film transistor 1 according to the first embodiment of the invention, it is possible to provide an organic thin film transistor with the electric characteristic improved by optimizing the structure and the impurity concentrations of the organic semiconductor layer 40. Specifically, the impurity concentration N1 of the high-concentration regions 41 of the organic semiconductor layer 40, which are located under the source and drain electrodes 50 and 60, is set higher than the impurity concentration N2 of the low-concentration region 42 of the organic semiconductor layer 40, which is located above the gate electrode 20 between the source and drain electrodes 50 and 60. Therefore, carriers are supplied from the high-concentration region 41 to increase the concentration of carriers in the organic semiconductor layer 40, thus preventing the lack of carriers in the organic semiconductor layer 40. This results in an increase in the current amplification factor of the organic thin film transistor 1. Accordingly, it is possible to constitute a high-performance circuit using the organic thin film transistor 1 with the electric characteristics improved. For example, if the organic thin film transistor 1 is used to constitute each of the pixel transistors and peripheral circuits, a flexible device, a printable device, or the like can be implemented with only organic thin film transistors.

With reference to FIGS. 8 to 12, a description is given of a method of manufacturing the organic thin film transistor 1 according to the first embodiment of the invention. The following method of manufacturing the organic thin film transistor 1 is shown by example. It is certain that the method of manufacturing the organic thin film transistor 1 can be implemented by other various manufacturing methods including modifications thereof.

(a) A thin film 100 for liftoff is formed on the entire surface of the substrate 10 as an insulator substrate, and then using photolithography and etching, a part of the lift-off thin-film 100 is removed to expose a region of the surface of the substrate 10 where the gate electrode 20 is to be formed. As shown in FIG. 8, an opening 101 is thus formed. The thin film 100 for liftoff can be made of a photoresist film or the like.

(b) As shown in FIG. 9, a gate electrode layer 200 having a predetermined thickness is then formed on the substrate 10 and liftoff thin-film 100 so as to fill the opening 101. As the gate electrode layer 200, an aluminum film with a thickness of about 0.3 μm is formed, for example. The material and thickness of the gate electrode layer 200 can be arbitrarily selected.

(c) The lift-off thin film 100 is removed to form the gate electrode 20 by a lift-off process as shown in FIG. 10.

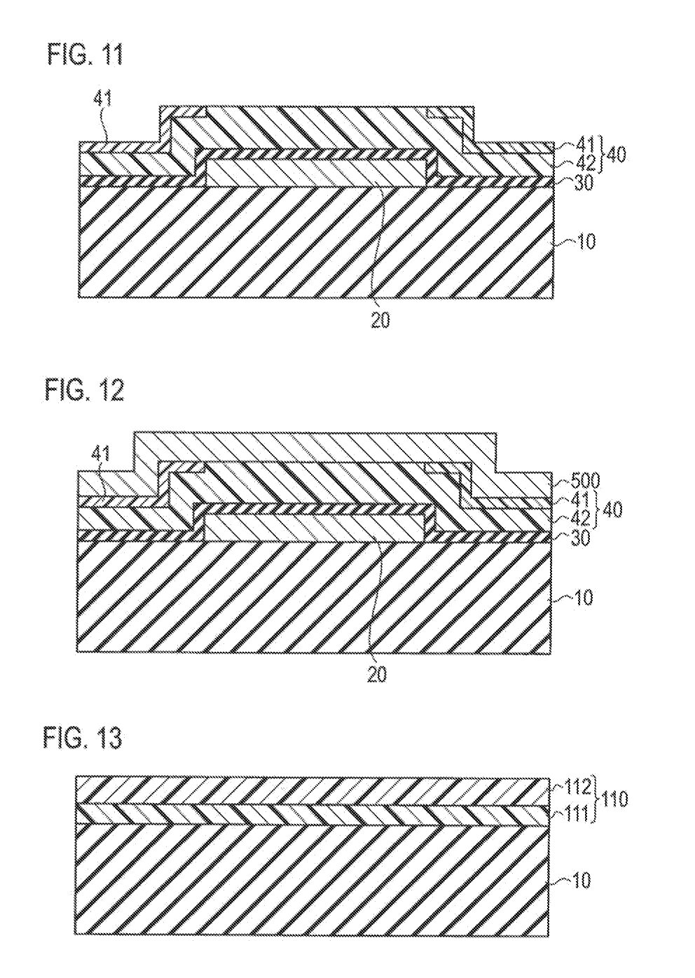

(d) As the gate insulating film 30, a silicon oxide film with a thickness of 300 nm, for example, is formed on the substrate 10 and gate electrode 20. Furthermore, on the gate insulating film 30, for example, a pentacene film with a thickness of 30 nm is formed as the organic semiconductor layer 40. As shown in FIG. 11, the high-concentration regions 41 are formed so as to be located at the predetermined position, that is, under the source and drain electrodes 50 and 60 in the organic semiconductor layer 40. For example, the high-concentration regions 41 are formed by a coating process, for example.

(e) As shown in FIG. 12, on the organic semiconductor layer 40, a 10 to 100 nm thick electrode film 500 made of Al, Ca, or the like is formed. Subsequently the electrode film 500 is patterned to form the source and drain electrodes 50 and 60. The organic thin film transistor 1 according to the first embodiment of the invention is thus completed.

The gate insulating film 30, organic semiconductor layer 40, electrode film 500 can be formed by spattering, vapor deposition, or the like. The source and drain electrodes 50 and 60 can be formed using photolithography and liftoff or using photolithography and etching.

Upper part or all of each predetermined region of the organic semiconductor layer 40 in the thickness direction may be etched using the photoresist film patterned using photolithography as a mask, and the high-concentration regions 41 are formed in the etched regions. Alternatively, the high-concentration regions 41 may be formed by doping p-type impurities in the predetermined regions of the organic semiconductor layer 40.

In the above example, the gate electrode 20 is formed by using a liftoff process. However, the gate electrode 20 may be formed using an etching process. Alternatively, the gate electrode 20 may be formed by using a liftoff process with a double-layer resist process applied thereto. Hereinafter, with reference to FIGS. 13 to 15, an example of manufacturing the organic thin film transistor 1 by applying the double layer resist process is described.

(a) As shown in FIG. 13, polydimethylglutarimide (PMGI) is applied on the substrate 10 up to a thickness of 200 nm by spin coating as a lower resist film 111. Positive photoresist (OFPR) is applied on the lower resist film 111 by spin coating as an upper resist film 112 up to a thickness of 500 nm. A double layer resist film 110 is thus formed on the substrate 10.

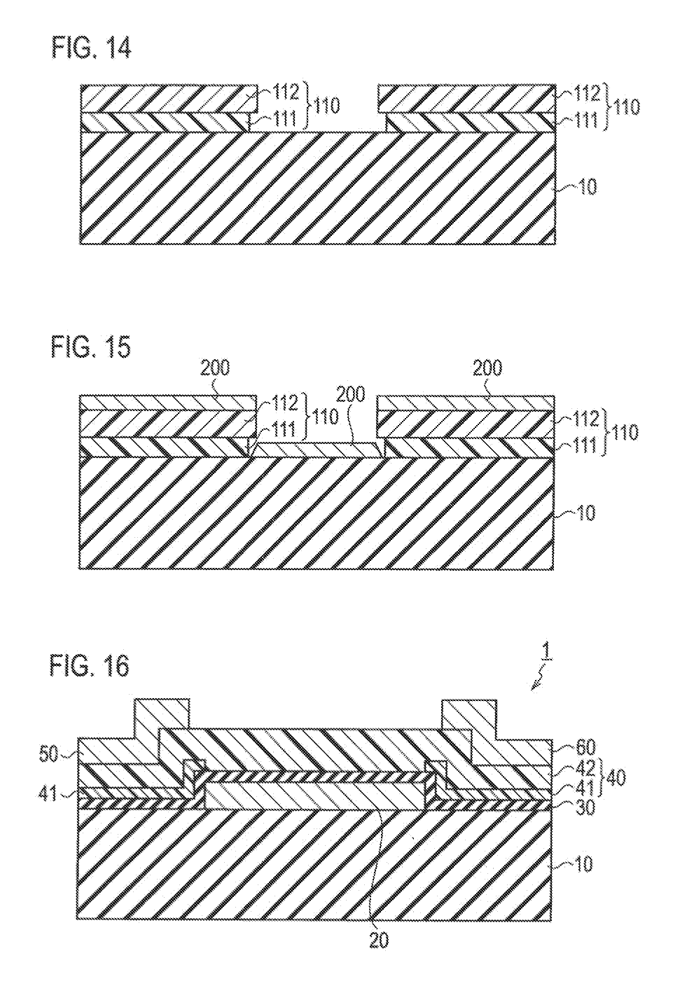

(b) A desired pattern is transferred to the double layer resist film 110 by an ultraviolet exposure process and is then developed to expose a region of the surface of the substrate 10 where the gate electrode 20 is to be placed. The cross-sectional structure shown in FIG. 14 is thus obtained. At this time, since the etching rate of the lower resist film 111 is higher than that of upper resist film 112, the upper resist film 112 protrudes in space over the region where the surface of the substrate 10 is exposed, forming an overhang structure. The amount of overhang is determined by the difference between rates at which OFPR and PMGI dissolve in a developer.

(c) As shown in FIG. 15, the gate electrode layer 200 is formed on the substrate 10 and double layer resist film 110 by vapor deposition process. The double layer resist film 110 is then removed, forming the gate electrode 20 by liftoff in a similar manner to the method described with reference to FIG. 10. The subsequent processes are the same as the processes previously described with reference to FIGS. 10 to 12.

According to the double layer resist process described above, the overhang structure with the upper resist film 112 protrudes into space more than the lower resist film 111. Accordingly, each edge of the gate electrode 20 has a gentle slope structure as shown in FIG. 15. This can prevent a so-called cutting phenomenon in steps in which the gate insulating film 30 and organic semiconductor layer 40 deposited on the gate electrode 20 are not continuous at the edge of the gate electrode 20.

According to the aforementioned method of manufacturing the organic thin film transistor 1, the impurity concentration N1 of the high-concentration regions 41 located under the source and drain electrodes 50 and 60 are set higher than the impurity concentration N2 of the low-concentration region 42 located above the gate electrode 20. It is therefore possible to provide an organic thin film transistor with the lack of carriers in the organic semiconductor layer 90 prevented.

### Modification

FIG. 16 shows the organic thin film transistor 1 according to a modification of the first embodiment of the invention. The organic thin film transistor 1 shown in FIG. 16 differs from that shown in FIG. 1 in that the high-concentration regions 41 are located on the gate insulating film 30 side of the organic semiconductor layer 40. In the organic thin film transistor 1 shown in FIG. 1, the high-concentration regions 41 are in contact with the source and drain electrodes 50 and 60. On the other hand, in the organic thin film transistor 1 shown in FIG. 16, the high-concentration regions 41 are in contact with the gate insulating film 30 and are separated from the source and drain electrodes 50 and 60. The other configuration thereof is the same as the organic thin film transistor 1 shown in FIG. 1.

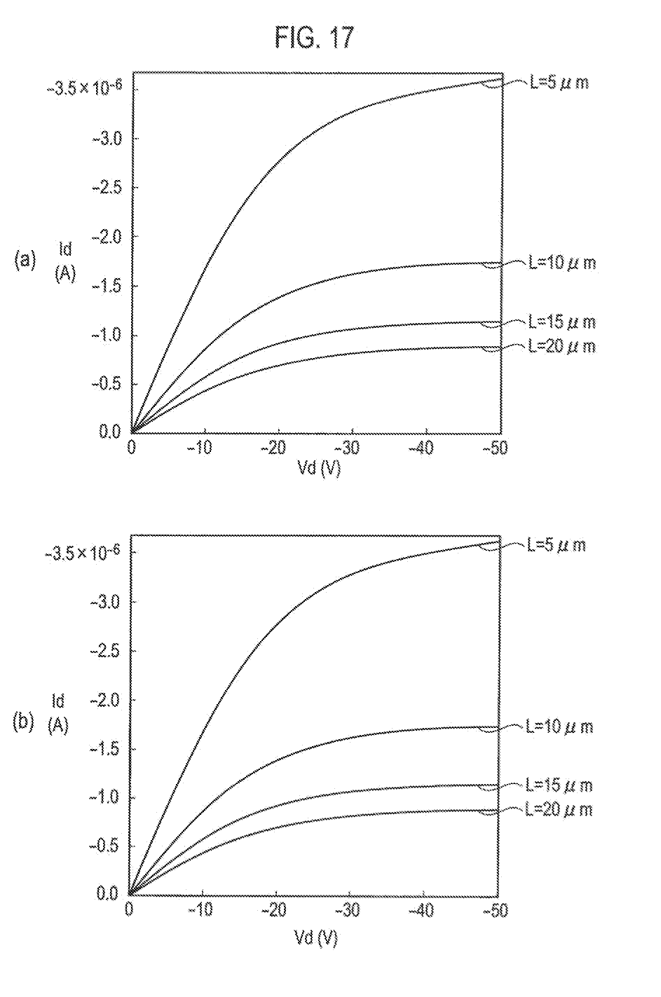

FIGS. 17(a) and 17(b) show current-voltage characteristics of the drain current Id and drain voltage Vd which are obtained by device simulation for the organic thin film transistors 1 shown in FIGS. 1 and 16 with the channel length L varying between 5 and 20 μm, respectively. The thickness d2 of the organic semiconductor layer 40 is 30 nm; the impurity concentration N2 of the low-concentration regions 42 is 1×10¹⁵ cm⁻³; the thickness d1 of the high-concentration region 41 is nm; and the impurity concentration N1 of the high-concentration regions 41 is 1×10²⁰ cm⁻³. The thickness dg of the gate insulating film 30 is 300 nm; the gate voltage Vg is −30 V; and the drain voltage Vd is 0 to −50V.

The comparison between FIGS. 17(a) and 17(b) reveals that the organic thin film transistors 1 thereof have the same current-voltage characteristics. In other words, the effect on improving the performance can be provided regardless of the positions of the high-concentration regions 41 in the organic semiconductor layer 40 in the thickness direction if the high-concentration regions 41 are located near the source electrode 50 and near the drain electrode 60.

The organic thin film transistor 1 shown in FIG. 16 is manufactured by forming the high-concentration regions 41 in the predetermined regions on the gate insulating film 30 by coating or the like and forming a pentacene film on the high-concentration regions 41 by vapor deposition or the like as the organic semiconductor layer 40.

FIG. 1 shows the example in which the high-concentration regions 41 are in contact with the source and drain electrodes 50 and 60, and FIG. 16 shows the example in which the high-concentration regions 41 are in contact with the gate insulating film 30. However, in order to supply and accumulate carriers in the organic semiconductor layer 40, the high-concentration regions 41 only need to be individually located near the source electrode 50 and drain electrode 60. Accordingly, the high-concentration regions 41 may be surrounded by the low-concentration region 42.

Alternatively, the high-concentration regions 41 may be the entire regions of the organic semiconductor layer 40 under the source and drain electrodes 50 and 60 in the thickness direction. In this case, the high-concentration regions 41 are in contact with the source and drain electrodes 50 and 60 and are also contact with the gate insulating film 30. Moreover, the high-concentration regions 41 may be formed in regions of the organic semiconductor layer 40 which are in contact with the source and drain electrodes 50 and 60 partially in the planar direction and in the thickness direction.

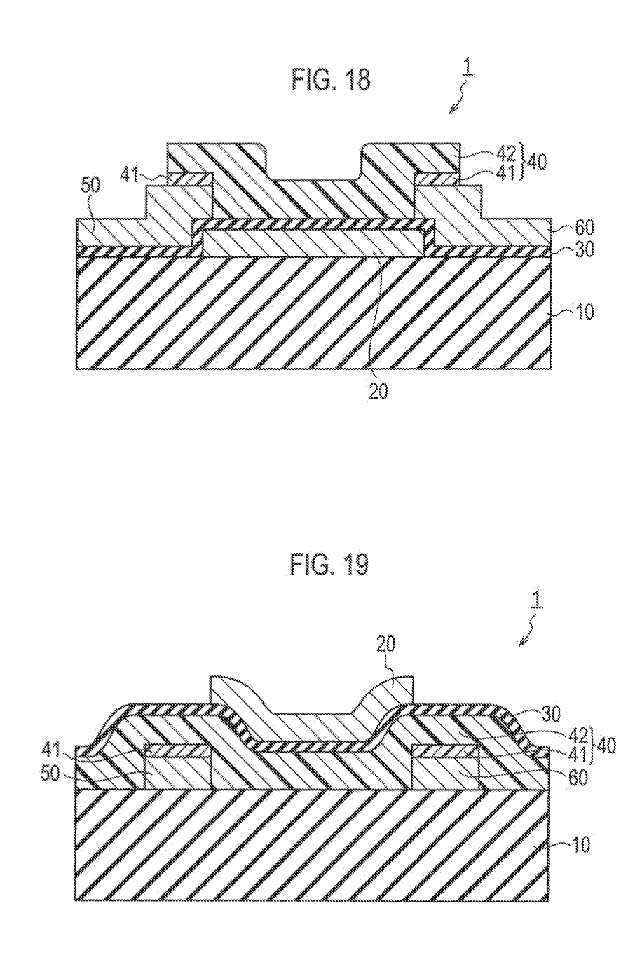

The positional relationship of the gate electrode 20, organic semiconductor layer 40, and source and drain electrodes 50 and 60 is not limited to the first embodiment shown in FIG. 1. The organic thin film transistor 1 only should have an organic TFT structure in which the high-concentration regions 41 are located near the source electrode 50. In the first embodiment shown in FIG. 1, the organic semiconductor layer 40 is located on the gate insulating film 30 above the gate electrode 20, and the source and drain electrodes 50 and 60 are located on the organic semiconductor layer 40. However, as shown in FIG. 18, for example, the organic thin film transistor 1 may have a structure in which the organic semiconductor layer 40 is located on the source and drain electrodes 50 and 60. Specifically, the organic thin film transistor 1 shown in FIG. 18 includes: the gate electrode 20 located on the substrate 10; the gate insulating film 30 located on the gate electrode 20; the source and drain electrodes 50 and 60 located on the gate insulating film 30 so as to be separated from each other; and the organic semiconductor layer 40 continuously located on the source and drain electrodes 50 and 60. The impurity concentration N1 of the high-concentration regions 41 of the organic semiconductor layer 40, which are located on the source electrode 50 and the drain electrode 60, is set higher than the impurity concentration N2 of the low-concentration region 42 of the organic semiconductor layer 40, which is located above the gate electrode 20 between the source and drain electrodes 50 and 60.

Alternatively, as shown in FIG. 19, the organic thin film transistor 1 may have a structure in which the organic semiconductor layer 40 is located on the source and drain electrodes 50 and 60 and the gate insulating film 30 and gate electrode 20 are located on the organic semiconductor layer 40. The organic thin film transistor 1 shown in FIG. 19 includes: the source and drain electrodes 50 and 60 located on the substrate 10 so as to be separated from each other; the organic semiconductor layer 40 continuously located on the source and drain electrodes 50 and 60; the gate insulating film 30 located on the organic semiconductor layer 40; and the gate electrode 20 located on the gate insulating film 30. The impurity concentration N1 of the high-concentration regions 41 of the organic semiconductor layer 40, which are individually located on the source and drain electrodes 50 and 60, is set higher than the impurity concentration N2 of the low-concentration region 42 of the organic semiconductor layer 40, which is located under the gate electrode 20 between the source and drain electrodes 50 and 60.

FIGS. 18 and 19 show the examples in which the high-concentration regions 41 are in contact with the source and drain electrodes 50 and 60. However, as previously described, the high-concentration regions 41 only should be individually located near the source and drain electrodes 50 and 60.

In the modifications of the first embodiment shown in FIGS. 18 and 19, the impurity concentration N1 of the high-concentration regions 41 located near the source and drain electrodes 50 and 60 can be set higher than the impurity concentration N2 of the low-concentration region 42 in which the channel region is formed. Accordingly, it is possible to implement the organic thin film transistor 1 in which carriers are supplied to the channel region from the high-concentration regions 41 to prevent the lack of carriers in the organic semiconductor layer 40.

### Second Embodiment

An organic thin film transistor according to a second embodiment of the invention is a complementary organic thin film transistor including: an organic thin film transistor having majority carriers of a first conductivity type as main current; and an organic thin film transistor having majority carriers of a second conductivity type as main current. The first and second conductivity types are opposite to each other. The first conductivity type is n-type when the second conductivity type is p-type, and the first conductivity type is p-type when the second conductivity type is n-type. According to the complementary organic thin film transistor including an organic thin film transistor performing a p-channel operation using holes as the majority carriers (hereinafter, referred to as an p-channel organic thin film transistor) and an organic thin film transistor performing an n-channel operation using electrons as the majority carriers (hereinafter, referred to as an n-channel organic thin film transistor) which are formed on a same substrate, a high-performance circuit can be implemented similarly to silicon complementary MOS (CMOS) circuits.

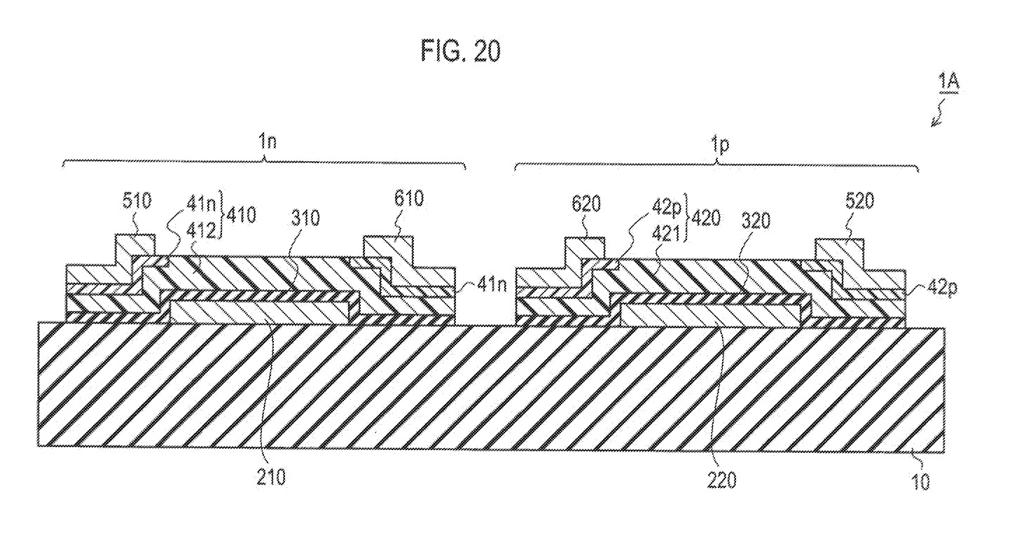

FIG. 20 shows an example of a complementary organic thin film transistor 1A in which an n-channel organic thin film transistor 1n and a p-type organic thin film transistor 1p are formed on a same substrate 10. Each of the n-channel and p-channel organic thin film transistors 1n and 1p has the same structure as the organic thin film transistor 1 shown in FIG. 1. High-concentration regions 41n of an organic semiconductor layer 410 of the n-channel organic thin film transistor 1n are n-type conductors, and high-concentration regions 41p of an organic semiconductor layer 420 of the p-channel organic thin film transistor 1p are p-type conductors. The n-channel and p-channel thin film transistors 1n and 1p are the same only excepting the conductivity types of the high-concentration regions 41n and 41p.

The n-channel organic thin film transistor 1n includes: the organic semiconductor layer 410; source and drain electrodes 510 and 610 which are separated from each other and are in contact with the organic semiconductor layer 410; a gate insulating film 310 which is in contact with the organic semiconductor layer 410 between the source and drain electrode 50 and 60; and a gate electrode 210 which is opposed to the organic semiconductor layer 40 and is in contact with the gate insulating film 310. The impurity concentration of high-concentration regions 41n of the n-type conductor in the organic semiconductor layer 410, which are located near the source and drain electrodes 510 and 610, is set higher than the impurity concentration of a low-concentration region 412 in the organic semiconductor layer 910, which is located near the gate electrode 20 in the thickness direction of the organic semiconductor layer 910 between the source and drain electrodes 510 and 610. The impurity concentration of the high-concentration regions 41n, which are located near the source and drain electrodes 510 and 610 in the thickness direction of the organic semiconductor layer 410, is higher than the impurity concentration of the channel region of the n-channel organic thin film transistor 1n. The low-concentration region 412 may be either a p-type or an n-type conductor.

On the other hand, the p-channel organic thin film transistor 1p includes: the organic semiconductor layer 420; source and drain electrodes 520 and 620 which are separated from each other and are in contact with the organic semiconductor layer 420; a gate insulating film 320 which is in contact with the organic semiconductor layer 420 between the source and drain electrodes 520 and 620; and a gate electrode 220 which is opposed to the organic semiconductor layer 420 and is in contact with the gate insulating film 320. The impurity concentration of high-concentration regions 42p of the p-type conductor in the organic semiconductor layer 420, which are individually located near the source and drain electrodes 520 and 620, is set higher than the impurity concentration of a low-concentration region 422 of the organic semiconductor layer 420, which is located near the gate electrode 220 in the thickness direction of the organic semiconductor layer 420 between the source and drain electrodes 520 and 620. In other words, the impurity concentration of the high-concentration regions 42p, which are located near the source and drain electrodes 520 and 620 in the thickness direction of the organic semiconductor layer 420, is set higher than the impurity concentration of the channel region of the p-channel organic thin film transistor 1p. The low-concentration region 422 may be either a p-type or an n-type conductor.

To be more specific, in the complementary organic thin film transistor 1A shown in FIG. 20, the gate electrodes 210 and 220 are located on the substrate 10, and the low-concentration regions 412 and 422 are located on the gate insulating films 310 and 320, respectively. On the organic semiconductor layers 910 and 420, the source electrodes 510 and 520 and the drain electrodes 610 and 620 are located. The high-concentration regions 41n as the n-type carrier high-concentration regions are individually located in contact with the source and drain electrodes 510 and 610. The high-concentration regions 42p as the p-type carrier high-concentration region are individually located in contact with the source and drain electrodes 520 and 620.

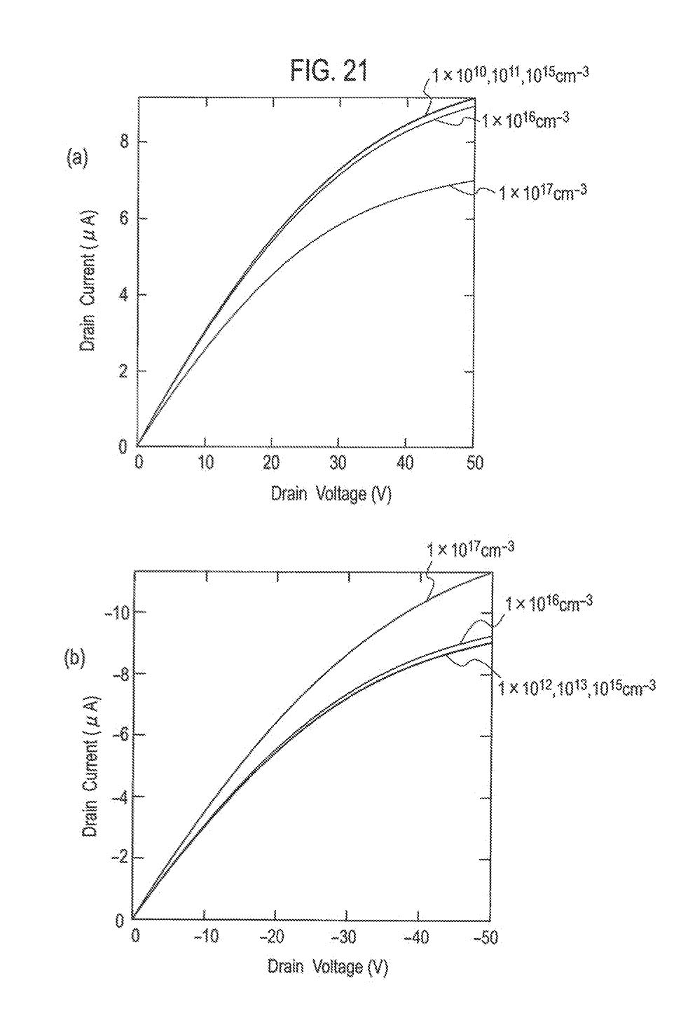

FIGS. 21(a) and 21(b) show results of device simulation for the n-channel and p-channel organic thin film transistors 1n and 1p, respectively. FIG. 21(a) shows device simulation results of the drain current-drain voltage characteristics of the n-channel organic thin film transistor 1n when the n-type carrier concentration of the high-concentration regions 41n is set to 1×10²⁰ cm⁻³. In the device simulation, the low-concentration region 412 constituting the channel region is a p-type conductor, and the p-type carrier concentration is varied to 1×10¹⁰, 1×10¹¹, 1×10¹⁵, 1×10¹⁶, and 1×10¹⁷ cm⁻³. FIG. 21(b) shows device simulation results of the drain current-drain voltage characteristics of the p-channel organic thin film transistor 1p when the p-type carrier concentration of the high-concentration regions 42p is set to 1×10²⁰ cm⁻³. In the device simulation, the low-concentration region 422 constituting the channel region is a p-type conductor, and the p-type carrier concentration is varied to 1×10¹², 1×10¹³, 1×10¹⁵, 1×10¹⁶, and 1×10¹⁷ cm⁻³. The gate voltage in FIG. 21(a) is set to 50V, and the gate voltage in FIG. 21(b) is set to −50V. The carrier mobilities thereof are set to 0.3 cm²/Vs.

As apparent from FIGS. 21(a) and 21(b), when the concentrations of the high-concentration regions 41n and 42p are set to 1×10²⁰ cm⁻³, the n-channel and p-channel organic thin film transistors 1n and 1p in which the low-concentration regions 412 and 422 have concentrations in a range between 1×10¹⁰ and 1×10¹⁶ cm⁻³ have substantially a same drain current-drain voltage characteristic.

However, if the carrier concentration of the low-concentration region 412 is increased to 1×10¹⁷ cm⁻³, the carriers begin to be recombined to reduce the drain current in the n-channel organic thin film transistor 1n. If the carrier concentration of the low-concentration region 422 is increased to 1×10¹⁷ cm⁻³, leak current began to flow to increase the drain current in the p-channel organic thin film transistor 1p.

Based on the device simulation results shown in FIGS. 21(a) and 21(b), even if the organic semiconductor layer constituting the channel region is a p-type conductor, the complementary organic thin film transistor operation can be implemented by locating the n-type and p-type high-concentration regions near the source and drain electrodes. When the carrier concentrations of the high-concentration regions 41n and 41p are about 1×10²⁰ cm⁻³, it is preferable that the carrier concentrations of the low-concentration regions 412 and 422 are set to not more than 1×10¹⁷ cm⁻³. In other words, it is preferable that the carrier concentrations of the low-concentration regions 412 and 422 are lower. Similarly, even if the organic semiconductor layer constituting the channel region is an n-type conductor, the complementary organic thin film transistor operation can be implemented by locating the n-type and p-type high-concentration regions near the source and drain electrodes.

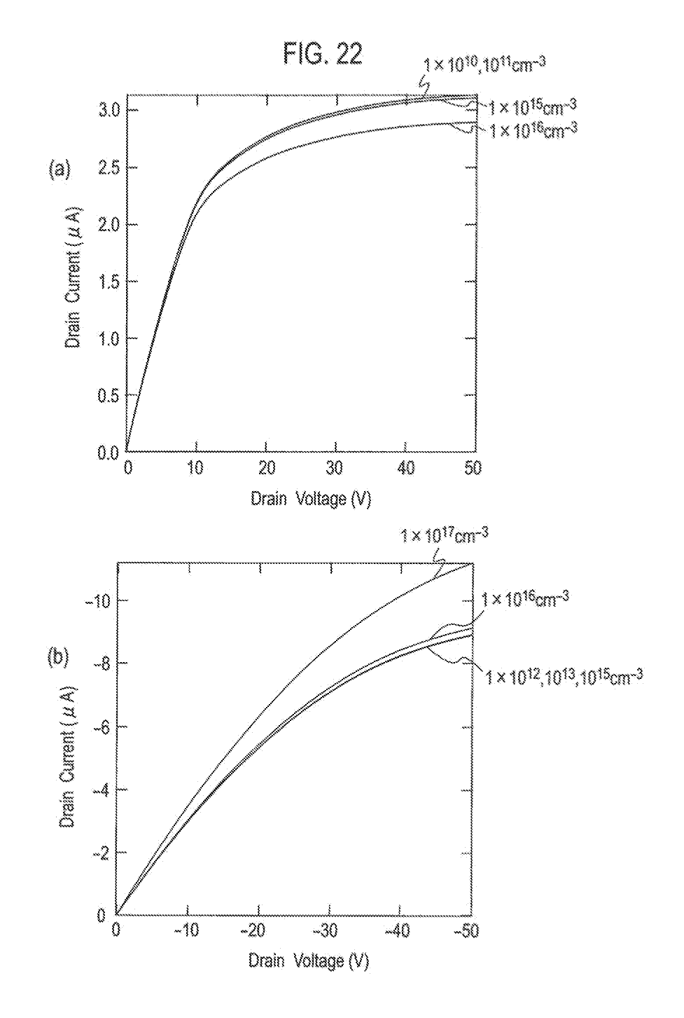

FIG. 22(a) shows device simulation results of the drain current-drain voltage characteristics of the n-channel organic thin film transistor in when the n-type carrier concentration of the high-concentration regions 41n is 1×10¹⁷ cm⁻³. FIG. 22(b) shows device simulation results of the drain current-drain voltage characteristics of the p-channel organic thin film transistor 1p when the p-type carrier concentration of the high-concentration region 41p is 1×10¹⁷ cm⁻³. The graph of FIG. 22(a) shows results of device simulation with the low-concentration region 412 being a p-type conductor and the p-type carrier concentration varying to 1×10¹⁰, 1×10¹¹, 1×10¹⁵, and 1×10¹⁶ cm⁻³. The graph of FIG. 22(b) shows results of device simulation with the low-concentration region 422 being a p-type conductor and the p-type carrier concentration thereof varying to 1×10¹², 1×10¹³, 1×10¹⁵, 1×10¹⁶, and 1×10¹⁷ cm⁻³.

As shown in FIGS. 21(a) and 21(b), the characteristics of the n-channel and p-channel organic thin film transistors 1n and 1p are substantially the same when the carrier concentrations of the high-concentration regions 41n and 42p are 1×10²⁰ cm³. However, as shown in FIGS. 22(a) and 22(b), when the carrier concentrations of the high-concentration regions 41n and 42p are set to 1×10¹⁷ cm⁻³, the drain current of the p-channel organic thin film transistor 1p is about three times as large as the drain current of the n-channel organic thin film transistor in, thus providing a better characteristic. This is because, in the case where the low-concentration regions 412 and 422 are made of p-type materials, the characteristic of the n-channel organic thin film transistor in is degraded due to the influence of the recombination of carriers in the low-concentration region 412 unless the carrier concentration of the high-concentration region 41n is made high enough.

Accordingly, it is preferable that the carrier concentration of the high-concentration regions 41n is two orders of magnitude higher than the carrier concentration of the low-concentration region 412. On the other hand, in the case where the low-concentration regions 412 and 422 are made of n-type, materials, the characteristic of the p-channel organic thin film transistor 1p is degraded unless the carrier concentration of the high-concentration 42p is made high enough. Accordingly, it is necessary to properly select the circuit configuration and parameters including the carrier concentrations of the high-concentration regions 41n and 42p according to whether each of the low-concentration regions 412 and 422 is an n-type or p-type conductor.

The n-channel and p-channel organic thin film transistors 1n and 1p shown in FIG. 20 are manufactured by the same method as the method of manufacturing the organic thin film transistor 1 described with reference to FIGS. 8 to 12 and 13 to 15. The complementary organic thin film transistor 1A is manufactured as follows, for example.

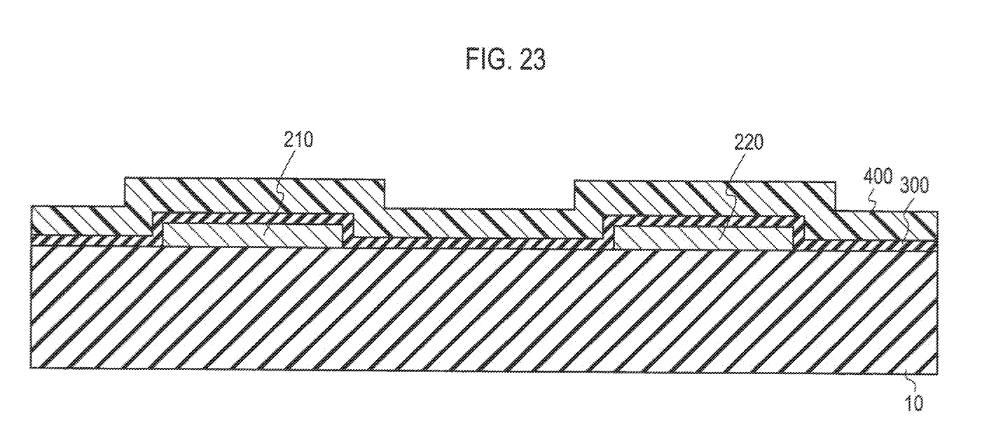

As shown in FIG. 23, a conductor layer is formed on the substrate 10 made of an insulator and is then patterned to form the gate electrodes 210 and 220. On the gate electrode 20, an insulating film 300 is formed. On the insulating film 300, an organic semiconductor film 400 is formed.

The substrate 10 may be a substrate of a silicon wafer with a thermal oxide film or the like formed thereon, a glass or crystal oxide substrate such as a silica glass or sapphire substrate, a plastic sheet, or the like. In short, the substrate 10 can be composed of any substrate made of an insulator.

The materials and thicknesses of the gate electrodes 210 and 220 are determined in the light of the desired transistor characteristics, structures of the gate electrodes 210 and 220 facilitating formation of the organic semiconductor film 400, and the like. The gate electrodes 210 and 220 can be formed by forming a metallic layer of Al, nickel (Ni), or the like by vapor deposition process, by applying fine particles of silver (Ag) or the like, and using an organic conductor such as polyacetylene.

The insulating film 300 is formed to a predetermined thickness so as to prevent occurrence of defects such as pin holes. The insulating film 300 can be formed using a process such as sputtering, vapor deposition, or coating, for example. The material of the insulating film 300 can be an insulator material generally used in a gate oxide film, such as an inorganic insulator including a silicon oxide film, a high-dielectric material such as tantalum oxide film, and an organic insulator.

The method of growing the organic semiconductor film 400 is not particularly limited and only should be a method capable of forming the organic semiconductor film 400 uniformly. The organic semiconductor film 400 can be formed by sputtering, laser deposition, CVD, coating, or the like, for example. The material of the p-type conductor can be pentacene, ruburene, or the like, and the material of the n-type conductor can be C60 or the like. The organic semiconductor film 400 can be made of a material generally used as an organic semiconductor. The organic semiconductor film 400 constituting the channel region can be made of an organic semiconductor which is conventionally not used because of the low carrier concentration thereof. This is because carriers in the channel region are supplied from the high-concentration regions 41n and 42p. This is a characteristic of the embodiment of the invention.

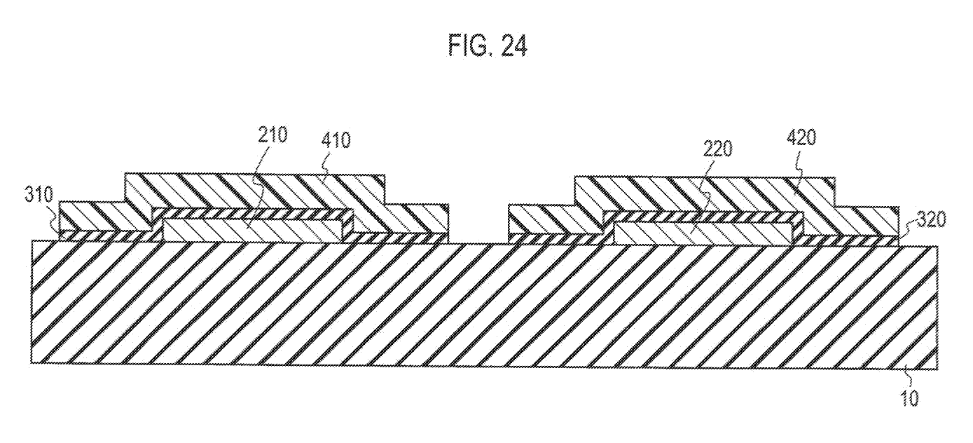

As shown in FIG. 24, the insulating film 300 and organic semiconductor film 400 are divided corresponding to the positions of the n-channel and p-channel organic thin film transistors 1n and 1p. The gate insulating films 310 and 320 and organic semiconductor layers 410 and 420 are thus formed.

Thereafter, the n-type high-concentration regions 41n are formed near regions where the source and drain electrodes 510 and 610 of the n-channel organic thin film transistor 1n are to be located. The p-type high-concentration regions 42p are formed near regions where the source and drain electrodes 520 and 620 of the p-channel organic thin film transistor 1p are to be located. The high-concentration regions 41n and 42p are formed by addition of a carrier inducing agent, deposition of a high-carrier concentration material, or the like. The material of the n-type high-concentration regions 41n can be alkali metal such as cesium. The material of the p-type high-concentration region 92p can be a halogen such as bromine, an oxide such as vanadium oxide, or the like. Forming the high-concentration regions 41n and 41p by using materials generating n-type or p-type carriers in the organic semiconductor layers 410 and 420, such as elements, compound materials, or organic materials, is within the scope of the organic thin film transistor according to the embodiment of the invention.

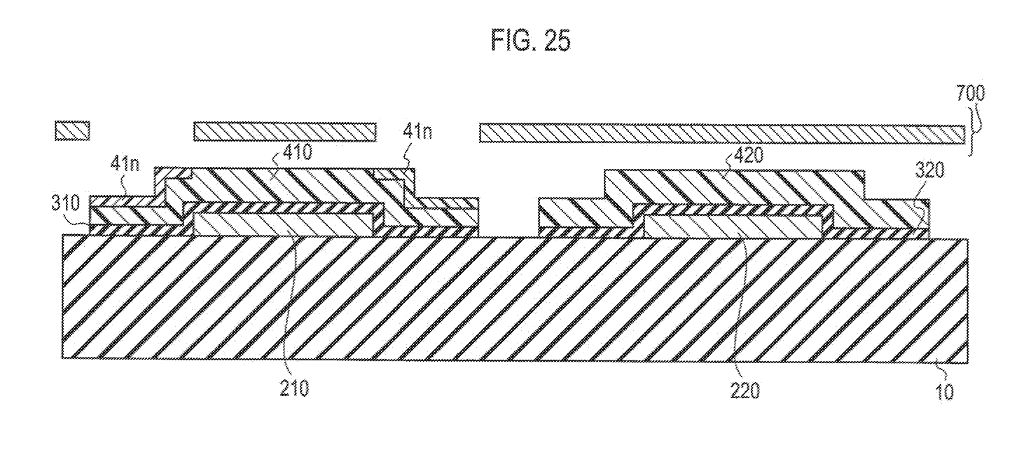

The high-concentration regions 41n and 42p of the n-channel and p-channel organic thin film transistors 1n need to include different types of impurities at high-concentrations. Accordingly, as shown in FIG. 25, the region other than where the high-concentration regions 41n are to be formed is covered with a mask 700 to form the high-concentration regions 41n by screen printing or the like. In a similar manner, the region other than where the high-concentration regions 42p are to be formed is covered with a mask to form the high-concentration regions 42p.

Subsequently, the source electrodes 510 and 520 and the drain electrodes 610 and 620 are formed at predetermined positions. In such a manner, the complementary organic thin film transistor 1A shown in FIG. 20 is completed. In the above-described method, the insulating film 300 and organic semiconductor film 400 are divided before the high-concentration regions 41n and 42p are formed. However, the insulating film 300 and organic semiconductor film 400 may be divided after the high-concentration regions 41n and 41p are formed.

As described above, the organic thin film transistor according to the second embodiment of the invention is characterized in that the material supplying electrons and supplying holes are selectively formed in the regions where the high-concentration regions 41n and 42p of the n-channel and p-channel organic thin film transistors 1n and 1p are to be located, respectively. The complementary organic thin film transistor 1A can be therefore manufactured using the organic semiconductor layers 410 and 420 of a same conductivity type. Accordingly, it is possible to implement a high-performance complementary organic thin film transistor while significantly reducing manufacturing cost.

In the complementary organic thin film transistor 1A shown in FIG. 20, the high-concentration regions 41n and 42p are respectively formed in the organic semiconductor layers 410 and 402 partially in the thickness direction. The regions where the high-concentration regions 41n and 42p are to be formed are not limited to the example shown in FIG. 20. The high-concentration regions 41n and 42p only should be located near the source electrodes 510 and 520 and the drain electrodes 610 and 620, respectively, and do not need to be in contact with the source electrodes 510 and 520 and the drain electrodes 610 and 620. Accordingly, the high-concentration regions 41n and 42p may be located so as to be surrounded by the low-concentration regions 412 and 422 or may be located near the interface between the organic semiconductor layer 410 and gate insulating film 310 and the interface between the organic semiconductor layer 420 and gate insulating film 320. The high-concentration regions 41n and 42p may be formed in the organic semiconductor layers 410 and 420 entirely in the thickness directions thereof. Alternatively, the high-concentration region 41n may be formed very thinnly in the interfaces between the source electrode 510 and the organic semiconductor layer 410 and between the drain electrode 610 and the organic semiconductor layer 410 while the high-concentration region 42p may be formed very thinnly in the interfaces between the source electrode 520 and the organic semiconductor layer 420 and between the drain electrode 620 and the organic semiconductor layer 420. For example, the high-concentration regions 41n and 42p have thicknesses of 0.1 nm.

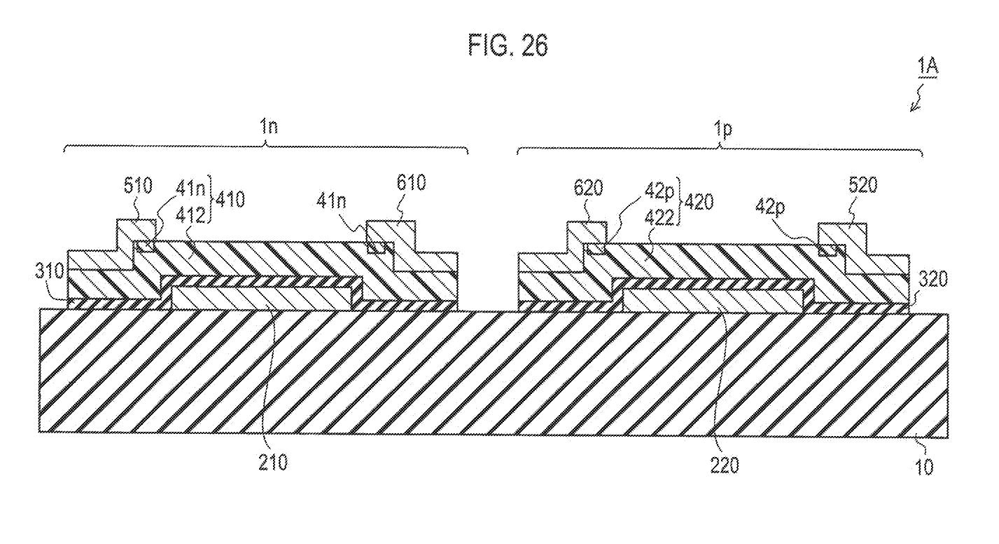

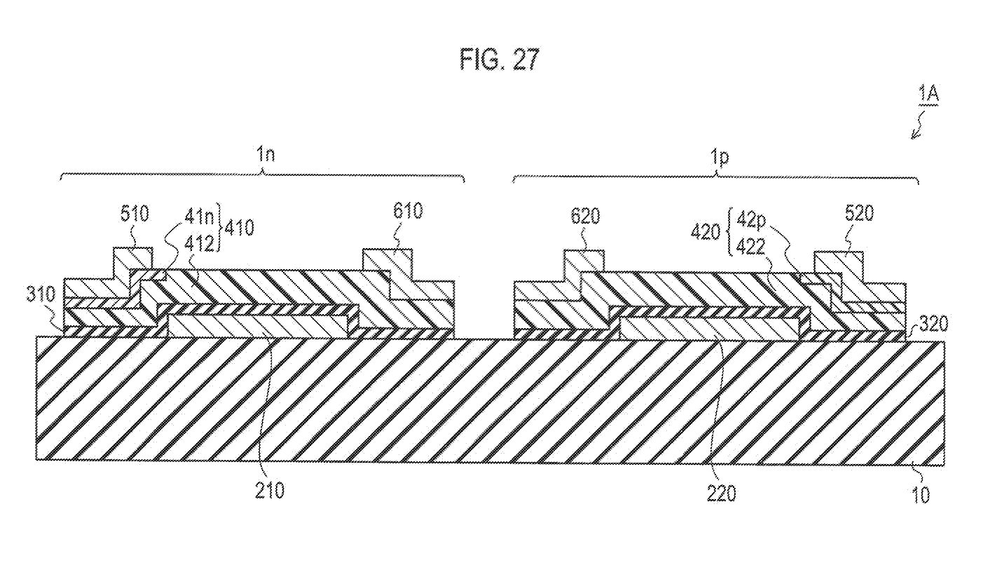

As shown in FIG. 26, the high-concentration regions 41n and 42p may be formed in portions of the organic semiconductor layers 410 and 402 which are in contact with the source electrodes 510 and 520 and the drain electrodes 610 and 620 partially in the planer direction and thickness direction. Alternatively, as shown in FIG. 27, the high-concentration regions 41n and 42p may be formed only near the source electrodes 510 and 520.

Generally, organic semiconductors are p-type, and it is very difficult to form n-type and p-type organic semiconductor layers from a same organic semiconductor material by controlling doping of impurities like silicon. Moreover, it is technically difficult to separately form organic semiconductors in the n-type and p-type regions on a plane.

However, in the complementary organic thin film transistor 1A according to the second embodiment of the invention, the organic semiconductor layers 410 and 420 of a same conductivity type include the high-concentration regions 41n and 42p, respectively. This allows the n-type region and p-type region to be separately formed in a plane. It is therefore possible to easily implement the complementary organic thin film transistor 1A including the n-channel and p-channel organic thin film transistors formed on a single substrate.

Furthermore, it is possible to implement a semiconductor integrated circuit which includes a plurality of the complementary organic thin film transistors 1A combined to execute various functions.

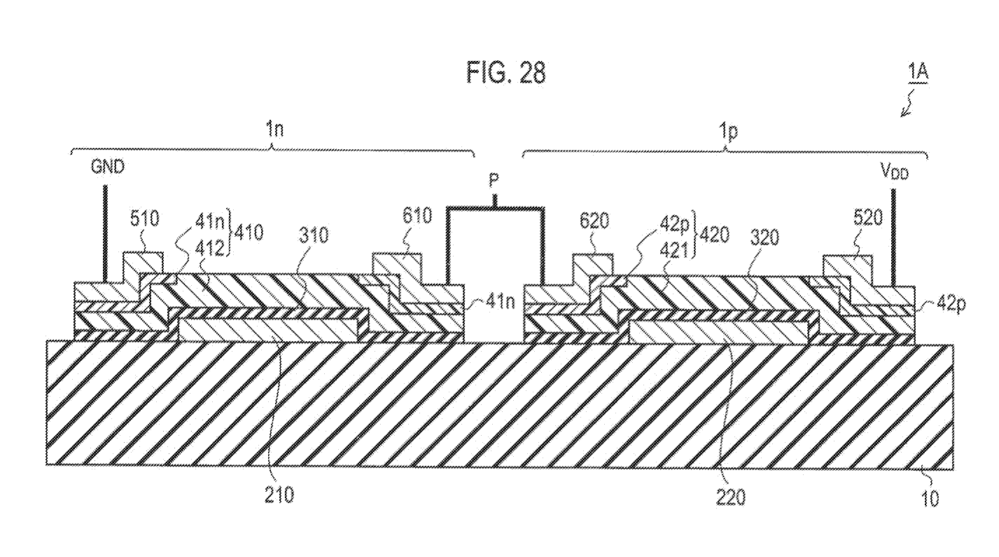

FIG. 28 shows an example in which the complementary organic thin film transistor 1A used as an inverter, for example. The source electrodes 510 and 520 of the n-channel and p-channel organic thin film transistors 1n and 1p are connected to a ground line GND and a power supply line V_{DD}, respectively. The drain electrodes 610 and 620 of the n-channel and p-channel organic thin film transistors 1n and 1p are connected to an output terminal P. If a signal is inputted to the gate electrodes 210 and 220 of the n-channel and p-channel organic thin film transistors 1n and 1p, an inverted signal of the inputted signal is outputted to the output terminal P.

As described above, it is known that combinations of the complementary transistors can constitute memory devices, logic circuits, and the like and can be applied to various usages.

In the example shown in FIG. 28, the p-channel and n-channel organic thin film transistors 1p and 1n are used as a load transistor and a drive transistor, respectively. However, it is certain that the configuration shown in FIG. 28 is one example. As previously described, the characteristics of the organic thin film transistors depend on the difference between carrier concentrations of the n-channel and p-channel thin film transistors 1n and 1p and the like. Accordingly, one of the n-channel and p-channel organic thin film transistors 1n and 1p which has larger drain current and better characteristics should be used as a drive transistor. In other words, using the n-channel organic thin film transistors in as a load resistor and p-channel organic thin film transistors 1p as a drive resistor is included in the second embodiment of the invention.

As described above, according to semiconductor integrated circuits including the complementary organic thin film transistors 1A, all the properties of CMOS circuit designs which have been accumulated can be used with silicon integrated circuit technologies. The complementary organic thin film transistor 1A can be therefore used in a significantly wider range of applications. Furthermore, since the complementary organic thin film transistor 1A can be manufactured by a non-expensive technique such as screen printing, it is possible to implement a fordable complementary organic thin film transistor at low cost. This enables printable and flexible systems.

As described above, the organic thin film transistor according to the second embodiment of the invention can implement the complementary organic thin film transistor 1A including the n-channel and p-channel organic thin film transistors 1n and 1p formed on the same substrate 10 by using the low-concentration regions 412 and 422, which are organic semiconductors with low carrier concentrations, as the channel regions and forming the high-concentration regions 41n of the n-type conductor with a high carrier concentration and high-concentration regions 41p of the p-type conductor with a high carrier concentration near the source electrodes. At this time, the high-concentration regions 41n and 42p only should be provided near the source electrodes. The complementary organic thin film transistor 1A is not limited to a top contact type in which the source and drain electrodes are provided above the organic semiconductor layer as shown in FIG. 20. In other words, even a complementary organic thin film transistor of a bottom contact type in which the source and drain electrodes are provided below the organic semiconductor layer as shown in FIGS. 18 and 19, for example, can also provide the above-described characteristic of the complementary organic thin film transistor 1A. As described above, the complementary organic thin film transistor 1A according to the second embodiment of the invention has a structure which has a very high flexibility in device manufacturing and is easily realized industrially.

### Other Embodiments

The invention is described with the first and second embodiments in the above, but it should not be understood that the invention is limited by the description and drawings constituting a part of this disclosure. From this disclosure, those skilled in the art will understand various substitutions, examples, and operational techniques.

In the above description of the first embodiment, the organic semiconductor layers 410 and 420 are p-type conductors. The organic semiconductor layers 410 and 420 may be n-type conductors. For example, the n-type high-concentration regions 41n and p-type high-concentration regions 41p may be formed in the predetermined regions of the organic semiconductor layers 410 and 420 made of fullerene (C60). Alternatively, the high-concentration regions 41n and low-concentration regions 412 may be configured to have different conductivity types while the high-concentration regions 42p and low-concentration region 422 are configured to have different conductivity types. The high-concentration regions 41n and low-concentration region 412 may be configured to have a same conductivity type while the high-concentration regions 42p and low-concentration region 422 are configured to have a same conductivity type.

As described above, it is certain that the invention includes various embodiments and the like not described in this disclosure. The technical scope of the invention is therefore determined by the features of the invention according to the claims which are appropriate based on the above description.

### INDUSTRIAL APPLICABILITY

The organic thin film transistor of the invention is applicable to electronic industries including manufacture manufacturing electronic devices such as flexible devices and printable devices including organic thin film transistors.

1. An organic thin film transistor, comprising:
an organic semiconductor layer;
a source electrode and a drain electrode which are separated from each other and are individually in contact with the organic semiconductor layer;
a gate insulating film which is in contact with the organic semiconductor layer between the source and drain electrodes; and
a gate electrode which is opposed to the organic semiconductor layer and is in contact with the gate insulating film, wherein
a high-concentration region of the organic semiconductor layer which is located near the source electrode has an impurity concentration higher than an impurity concentration of a low-concentration region of the organic semiconductor layer, the low-concentration region being located near the gate electrode in the thickness direction of the organic semiconductor layer between the source and drain electrodes.

2. The organic thin film transistor according to claim 1, wherein the high-concentration region has a thickness of not less than 0.1 nm.

3. The organic thin film transistor according to claim 1, wherein the high-concentration region has an impurity concentration of not less than 1×10¹⁶ cm⁻³.

4. The organic thin film transistor according to claim 1, wherein the high-concentration region is in contact with the source electrode.

5. The organic thin film transistor according to claim 1, wherein the high-concentration region is in contact with the gate insulating film.

6. An organic thin film transistor, comprising:
a substrate; and
first and second transistors which are separated from each other and are formed on the substrate, each of the first and second transistors including: an organic semiconductor layer; a source electrode and a drain electrode which are separated from each other and are individually in contact with the organic semiconductor layer; a gate insulating film which is in contact with the organic semiconductor layer between the source and drain electrodes; and a gate electrode which is opposed to the organic semiconductor layer and is in contact with the gate insulating film, wherein
in the first transistor, a high-concentration region of a first conductivity type in the organic semiconductor layer which is located near the source electrode has an impurity concentration higher than an impurity concentration of a low-concentration region in the organic semiconductor layer, the low-concentration region being located near the gate electrode in the thickness direction of the organic semiconductor layer between the source and drain electrodes, and
in the second transistor, a high-concentration region of a second conductivity type in the organic semiconductor layer which is located near the source electrode has an impurity concentration higher than an impurity concentration of a low-concentration region in the organic semiconductor layer, the low-concentration region being located near the gate electrode in the thickness direction of the organic semiconductor layer between the source and drain electrodes.

7. The organic thin film transistor according to claim 6, wherein each of the low-concentration regions of the first and second transistors has an impurity concentration of not more than 1×10¹⁷ cm⁻³.

8. The organic thin film transistor according to claim 6, wherein each of the high-concentration regions of the first and second transistors has an impurity concentration of not less than 1×10¹⁶ cm⁻³.

9. The organic thin film transistor according to claim 6, the high-concentration regions of the first and second transistors are in contact with the source electrodes of the first and second transistors, respectively.

10. The organic thin film transistor according to claim 6, the high-concentration regions of the first and second transistors are in contact with the gate insulating films of the first and second transistors, respectively.

11. A semiconductor integrated circuit, comprising:
a substrate; and
first and second transistors which are separated from each other and are formed on the substrate, each of the first and second transistors including: an organic semiconductor layer; a source electrode and a drain electrode which are separated from each other and are individually in contact with the organic semiconductor layer; a gate insulating film which is in contact with the organic semiconductor layer between the source and drain electrodes; and a gate electrode which is opposed to the organic semiconductor layer and is in contact with the gate insulating film, wherein
in the first transistor, a high-concentration region of a first conductivity type in the organic semiconductor layer which is located near the source electrode has an impurity concentration higher than an impurity concentration of a low-concentration region in the organic semiconductor layer, the low-concentration region being located near the gate electrode in the thickness direction of the organic semiconductor layer between the source and drain electrodes, and
in the second transistor, a high-concentration region of a second conductivity type in the organic semiconductor layer which is located near the source electrode has an impurity concentration higher than an impurity concentration of a low-concentration region in the organic semiconductor layer, the low-concentration region being located near the gate electrode in the thickness direction of the organic semiconductor layer between the source and drain electrodes.
